(19) United States
(12) Patent Application Publication
(10) Pub. No.: US 2017/0194600 A1
(43) Pub. Date: Jul. 6, 2017

(54) PACKAGING METHOD OF OLED DEVICE, PACKAGE STRUCTURE AND DISPLAY APPARATUS

(71) Applicant: BOE TECHNOLOGY GROUP CO., LTD., Beijing (CN)

(72) Inventors: Donghui YU, Beijing (CN); Chun Jan WANG, Beijing (CN)

(73) Assignee: BOE Technology Group Co., Ltd., Beijing (CN)

(21) Appl. No.: 15/321,374

(22) PCT Filed: Apr. 8, 2016
(86) PCT No.: PCT/CN2016/078848

§ 371 Date: Dec. 22, 2016

(30) Foreign Application Priority Data
May 7, 2015 (CN) 201510229716.3

(51) Int. Cl. H01L 51/52; H01L 51/56

(52) U.S. Cl. CPC H01L 51/5256; H01L 51/56; H01L 51/5246

(57) ABSTRACT

A packaging method of an OLED device, a packaging structure and a display apparatus. The packaging method of the OLED device comprising the following steps: providing a base substrate having the OLED device; forming a passivation layer on the surface of the OLED device; and forming a passivation reinforcement layer on the edge region of the passivation layer.

### TECHNICAL FIELD

Embodiments of the present invention relate to a packaging method and a package structure of an OLED device and a display device.

### BACKGROUND

Organic light emitting diode (OLED) devices are also known as organic electroluminescent diode devices. OLED devices receive wide attentions due to advantages such as self luminescence, rich colors, fast response, wide viewing angle, light weight, small thickness, low power consumption and capability of flexible display. OLED display devices are also regarded as display devices having great application prospects.

### SUMMARY

Embodiments of the present invention provide a packaging method of an organic light emitting diode (OLED) device, comprising: providing a base substrate formed with an OLED device; forming at least one passivation layer on a surface of the OLED device; and forming at least one passivation reinforcing layer on an edge of the at least one passivation layer.

In one embodiment of the present invention, for example, forming at least one passivation reinforcing layer on the edge of the at least one passivation layer comprises: forming a first reinforcing section on a partial region of the edge of the at least one passivation layer with a first mask; and forming a second reinforcing section on the edge of the at least one passivation layer with a second mask, wherein the first reinforcing section together with the second reinforcing section cover the edge of the passivation layer.

In one embodiment of the present invention, for example, the forming at least one passivation reinforcing layer on the edge of the at least one passivation layer comprises: forming the passivation reinforcing layer on the edge of the at least one passivation layer with a third mask.

In one embodiment of the present invention, for example, a measured thickness of the edge of the at least one passivation layer is less than or equal to one half of a preset thickness of the at least one passivation layer.

In one embodiment of the present invention, for example, a preset thickness of the at least one passivation reinforcing layer is greater than the measured thickness of the at least one passivation layer.

In one embodiment of the present invention, for example, forming a plurality of the passivation layers on the surface of the OLED device.

In one embodiment of the present invention, for example, the plurality of the passivation layers are a multi-layer stackup structure formed by alternatively stacking inorganic material and organic material.

In one embodiment of the present invention, for example, the method further comprising: forming an adhesive film on the at least one passivation layer and the at least one passivation reinforcing layer; cell-assembling a packaging cover plate with the base substrate by the adhesive film to form a cell, the OLED device, the at least one passivation layer and the at least one passivation reinforcing layer are located in the cell formed by the cover plate and the base substrate.

Embodiments of the present invention provide a packaging structure of an organic light emitting diode (OLED) device, comprising: at least one passivation layer overlaying on a surface of an OLED device on a base substrate, and at least one passivation reinforcing layer disposed on an edge of the at least one passivation layer.

In one embodiment of the present invention, for example, in the packaging structure of an organic light emitting device, a measured thickness of the edge of the at least one passivation layer is less than or equal to one half of a preset thickness of the at least one passivation layer.

In one embodiment of the present invention, for example, in the packaging structure of an organic light emitting device, a preset thickness of the at least one passivation reinforcing layer is greater than the measured thickness of the at least one passivation layer.

In one embodiment of the present invention, for example, in the packaging structure of an organic light emitting device, there are a plurality of the passivation layers.

In one embodiment of the present invention, for example, in the packaging structure of an organic light emitting device, the plurality of the passivation layers are a multi-layer stackup structure formed by alternatively stacking inorganic material and organic material.

In one embodiment of the present invention, for example, the packaging structure of an organic light emitting device further comprising: an adhesive film on the at least one passivation layer and the at least one passivation reinforcing layer, and a packaging cover plate cell-assembling with the base substrate through the adhesive film to form a cell.

Embodiments of the present invention provide a display device provided with the above described packaging structure of OLED devices.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a flow chart of a packaging method for an OLED device provided in an embodiment of the present invention;

FIG. 2 is a structure diagram of a passivation layer mask provided in an embodiment of the present invention;

FIG. 3 is a top view of a passivation layer formed on a surface of an OLED device provided in an embodiment of the present invention;

FIG. 4 is a structure diagram of a first mask provided in an embodiment of the present invention;

FIG. 5 is a structure diagram of a second mask provided in an embodiment of the present invention;

FIG. 6 is a structure diagram of a third mask provided in an embodiment of the present invention; and

FIG. 7 is a structure diagram of a package structure for an OLED device provided in an embodiment of the present invention.

### REFERENCE NUMERALS

11—Base substrate, 12—OLED device, 13—Passivation layer, 131—First region, 132—Second region, 14—Passivation reinforcing layer, 15—Adhesive film, 16—Packaging cover plate, 2—Passivation layer mask, 3—First mask, 4—Second mask, 5—Third mask, 6—Opening region.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

OLED devices are susceptible to oxygen and moisture. Therefore, it is usually necessary to package OLED devices. Due to the poor packaging effect for edges of an OLED device with conventional packaging methods, oxygen and moisture tend to enter the OLED device easily and result in defects such as black spots, pinholes, electrode oxidation and chemical reaction of organic materials, thereby severely reducing the service life of the OLED device.

As shown in FIG. 1, a packaging method of an OLED device provided in an embodiment of the present invention includes the following proceedings.

In S101, a base substrate formed with an OLED device is provided. A plurality of methods may be used to form the above-mentioned base substrate having OLED devices. For example, it is possible to form an OLED device structure on a surface of an array base substrate by evaporation.

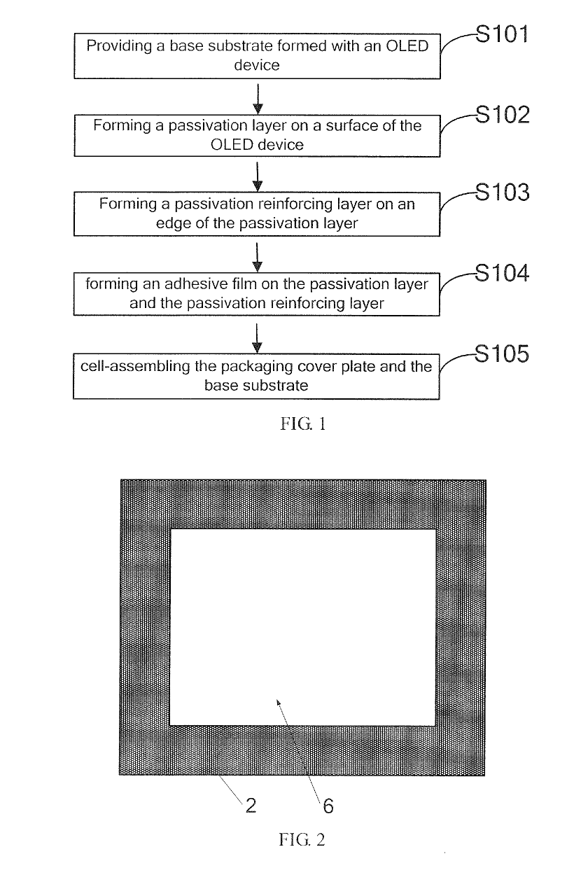

In S102, a passivation layer is formed on a surface of the OLED device. For example, firstly, as shown in FIG. 2, a passivation layer mask 2 is configured according to the size of the region on the base substrate on which the passivation layer is to be formed. Next, the passivation layer mask 2 is disposed over the base substrate to mask regions on the base substrate on which no passivation layer needs to be deposited with the passivation layer mask 2. Then, a passivation layer is deposited by a passivation layer deposition device on regions on the base substrate corresponding to opening regions 6 of the passivation layer mask 2, thereby forming the passivation layer on the surface of the OLED device.

In S103, a passivation reinforcing layer is formed on an edge of the passivation layer. For example, firstly, a passivation reinforcing layer mask is configured according to the locations and area sizes of regions on the base substrate on which the passivation reinforcing layer is to be formed. Next, the passivation reinforcing layer mask is disposed over the base substrate to mask regions on the base substrate where no passivation reinforcing layer needs to be deposited. Then, a passivation reinforcing layer is deposited by a passivation layer deposition device on regions on the base substrate corresponding to opening regions of the passivation reinforcing layer mask, thereby forming the passivation reinforcing layer on the edge of the passivation layer.

In conventional packaging methods for OLED devices, only a passivation layer is generally formed on a surface of OLED devices, and the thickness of the edge of the formed passivation layer is thin due to the limitation of process. While in the packaging method of OLED device provided in the embodiment of the present invention, a passivation reinforcing layer is formed on the edge of the passivation layer. Therefore, as compared to conventional packaging methods, the packaging method of OLED device provided in the embodiment of the present invention compensates for the thickness of the edge of the passivation layer, which can prevent oxygen and moisture from entering OLED devices due to the small thickness of the edge of the passivation layer, improves the packaging effect of OLED devices, and thereby effectively prolongs a service life of OLED devices. In addition, forming a passivation reinforcing layer on the edge of the passivation layer may enhance wear resistance of the edge of the passivation layer and make the edge of the passivation layer not easy to crack off, thereby enhancing the firmness of the passivation layer.

In the above-mentioned embodiments, the passivation reinforcing layer may be formed on the edge of the passivation layer in a plurality of ways. For example, the region on the base substrate on which the passivation reinforcing layer needs to be formed is divided into a plurality of subregions, and a passivation reinforcing layer mask is configured for each subregion. Utilizing the plurality of passivation reinforcing layer masks, the passivation reinforcing layer is formed on the region on the base substrate on which the passivation reinforcing layer is to be formed. Alternatively, a passivation reinforcing layer mask is disposed and regions on the base substrate on which no passivation reinforcing layer is to be formed are masked with the passivation reinforcing layer mask, thereby forming the passivation reinforcing layer on the region on which the passivation reinforcing layer is to be formed. Realization examples are as follows.

In realization example I, forming the passivation reinforcing layer on the edge of the passivation layer includes:

masking regions other than the edge of the passivation layer with the first mask to form a first reinforcing section on the edge of the passivation layer; and

masking the first reinforcing section and regions on the base substrate on which no passivation reinforcing layer is to be formed with the second mask to form a second reinforcing section on the edge of the passivation layer.

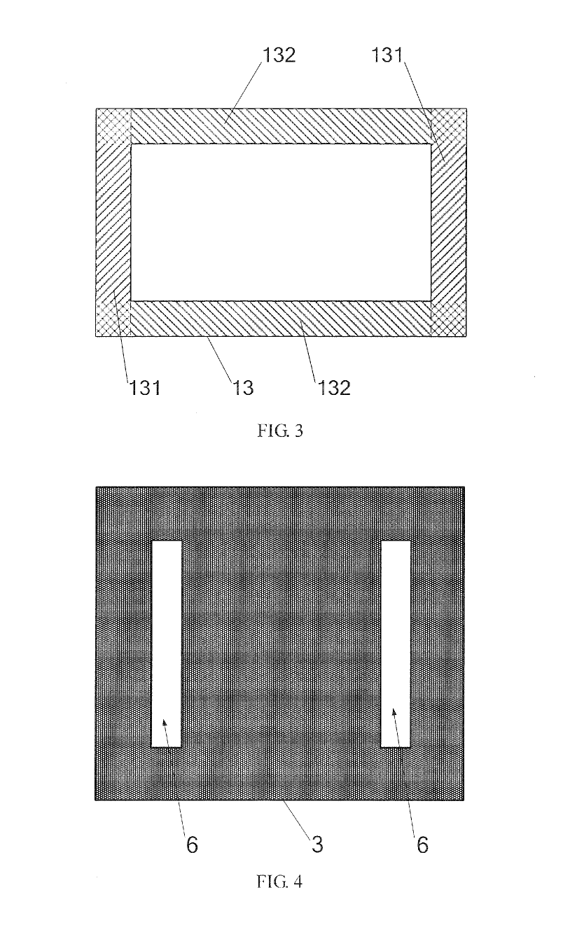

As shown in FIG. 3, the edge of the passivation layer 13 is divided into a first region 131 and a second region 132 that together surround the edge of the passivation layer 13 and the forming the passivation reinforcing layer on the edge of the passivation layer 13 includes:

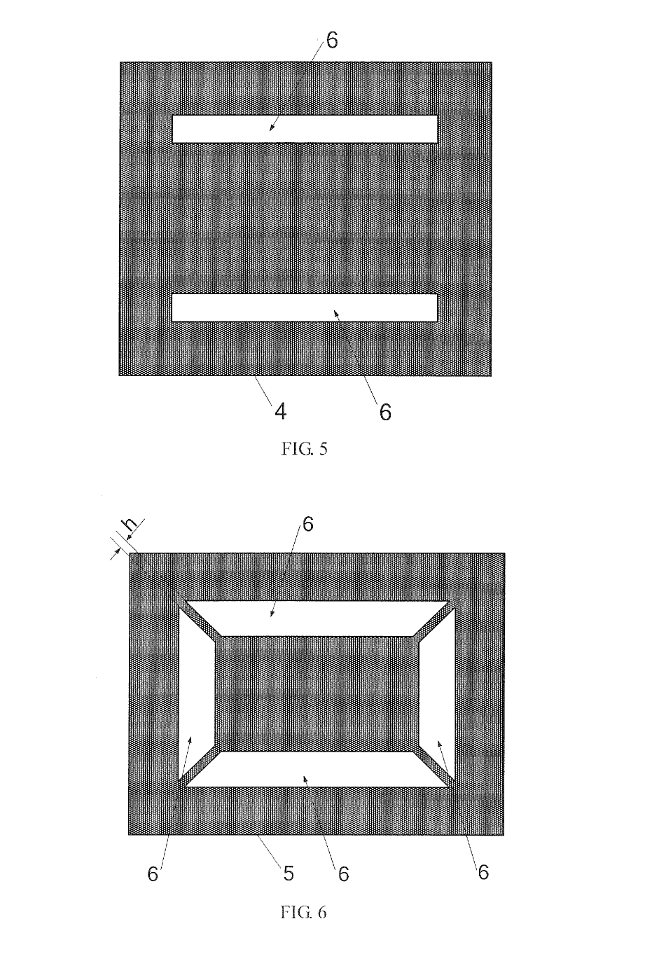

as shown in FIG. 4, configuring an opening region 6 of the first mask 3 according to the shape and area of the first region 131;

disposing the first mask 3 over the base substrate and masking regions other than the first region 131 on the base substrate with the first mask 3 with the opening region 6 of the first mask 3 corresponding to the first region 131;

forming a first reinforcing section on the first region 131 with the passivation layer deposition device;

as shown in FIG. 5, configuring an opening region 6 of the second mask 4 according to the shape and area of the second region 132;

disposing the second mask 4 over the base substrate and masking regions other than the second region 132 on the base substrate with the second mask 4 with the opening region 6 of the second mask 4 corresponding to the second region 132; and

forming a second reinforcing section on the second region 132 with the passivation layer deposition device, thereby forming the passivation reinforcing layer on the edge of the passivation layer 13.

The edge of the passivation layer 13 is divided into a first region 131 and a second region 132, and a first reinforcing section is formed on the first region 131, a second reinforcing section is formed on the second region 132, thereby forming the passivation reinforcing layer on the edge of the passivation layer 13. To sum up, the opening region 6 of the first mask 3 and the opening region 6 of the second mask 4 are designed respectively according to the shape and area of the edge of the passivation layer; a first reinforcing section is formed with the assistance of the first mask 3, and a second reinforcing section is formed with the assistance of the second mask 4, with the second reinforcing section overlapping the first reinforcing section to ensure that the passivation reinforcing layer completely covers the region on the base substrate on which the passivation reinforcing layer is to be formed, thereby improving the packaging effect of the OLED devices and prolonging the service life of OLED devices.

For example, there may be a plurality of ways for configuring opening regions 6 of the first and second masks 3 and 4. Generally, opening regions 6 of the first mask 3 and the second mask 4 may be configured according to the shape and area of the region on the base substrate on which the passivation reinforcing layer is to be formed.

In realization example II, forming the passivation reinforcing layer on the edge of the passivation layer includes:

masking regions other than the edge of the passivation layer 13 with the third mask to form the passivation reinforcing layer on the edge of the passivation layer 13.

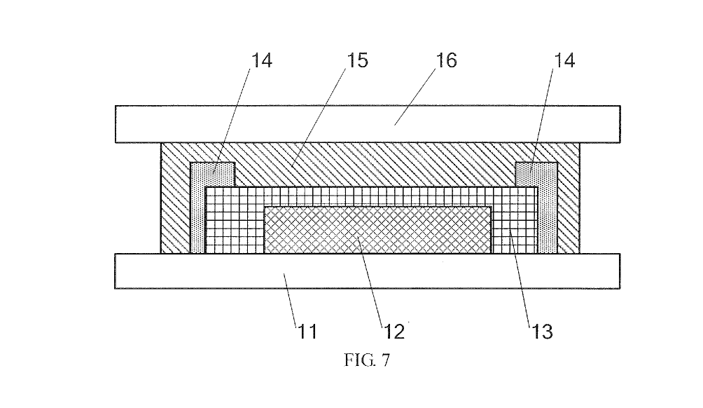

For example, firstly, as shown in FIG. 6, the third mask 5 is designed according to the region on the base substrate on which the passivation reinforcing layer is to be formed. The third mask 5 is provided with four strip-shaped opening regions 6 that form together a ring-like shape. Next, the third mask 5 is disposed over the base substrate and the third mask 5 masks regions other than the edge of the passivation layer 13 on the base substrate with the opening regions 6 of the third mask 5 corresponding to the edge of the passivation layer 13. Then, the passivation reinforcing layer is formed on the edge of the passivation layer 13 with the passivation layer deposition device. In order to prevent the opening regions 6 of the third mask 5 from deforming due to the large area of the third mask 5 and the gravity effect, separating sections are provided between adjacent opening regions 6 of the third mask 5 which have a width h greater than or equal to 0.1 cm.

Regions on the base substrate on which no passivation reinforcing layer is to be formed are masked with the third mask and a passivation reinforcing layer is formed on the edge of the passivation layer 13. As compared to realization example I, the number of used masks and the time for forming the passivation reinforcing layer are reduced, thereby saving costs and time.

In conventional packaging methods, the passivation layer 13 formed on the surface of OLED devices is generally thick in the middle region while thin in the edge region. In order to improve the packaging effect of OLED devices and enhance firmness and wear resistance of the passivation layer 13, for example, in the packaging method of OLED device provided in embodiments of the present invention, a region of the passivation layer 13 of which the measured thickness is less than or equal to one-half of the preset thickness of passivation layer 13 is regarded to be the edge of the passivation layer 13, namely the region on which the passivation reinforcing layer is to be formed. For example, first, after forming the passivation layer 13 on the surface of OLED devices, the base substrate is removed and thicknesses of regions of the passivation layer 13 formed on the surface of OLED devices are measured. Next, the measured thicknesses by measurement are compared against the preset thickness value of the passivation layer 13 and a region on the passivation layer 13 of which the measured thickness is less than or equal to one-half of the preset thickness is marked, which is the region on which the passivation reinforcing layer is to be formed. Then, the opening region 6 of the passivation reinforcing layer mask is configured according to the marked region. Then, the passivation reinforcing layer mask is disposed over the base substrate and masks regions on the base substrate on which no passivation reinforcing layer is to be formed, and the passivation reinforcing layer is formed on the region corresponding to the opening region 6 of the passivation reinforcing layer mask. In this way, it is possible to enhance water-tightness and oxygen-tightness of the weak region of the passivation layer 13, and to improve the packaging effect of OLED devices and prolong the service life of OLED devices. It is to be noted that the outer boundary of the passivation reinforcing layer may coincide with the location of the passivation layer 13 of which the measured thickness is one tenth of the preset thickness of the passivation layer 13, with the outer boundary of the passivation layer 13, or is beyond the outer boundary of the passivation layer 13.

It is to be noted that, when all regions of the passivation layer 13 have a thicknesses that is greater than one half of the preset thickness of the passivation layer 13, no passivation reinforcing layer may be formed on the edge of the passivation layer 13.

In the packaging method of OLED devices provided in embodiments of the present invention, the preset thickness of the passivation reinforcing layer is greater than the measured thickness of the edge of the passivation layer 13. For example, it is possible to set the thickness of the passivation reinforcing layer according to the area of the region on the base substrate on which passivation reinforcing layer is to be formed. If the area of the region on which passivation reinforcing layer is to be formed is relatively large, the preset thickness of the passivation reinforcing layer is the same as the preset thickness of the passivation layer 13, or the preset thickness of the passivation reinforcing layer is larger than the preset thickness of the passivation layer 13 to compensate for the thickness of the edge of the passivation layer 13. If the area of the region on which passivation reinforcing layer is to be formed is small, the preset thickness of the passivation reinforcing layer is smaller than the preset thickness of the passivation layer 13, and the preset thickness of the passivation reinforcing layer is larger than the measured thickness of the edge of the passivation layer 13 to avoid unevenness of the upper surface of OLED devices due the large preset thickness of the passivation reinforcing layer after completing the formation of the passivation reinforcing layer.

In the above-mentioned embodiments, the number of layers of the passivation layers 13 formed on the surfaces of OLED devices may be one or more; and the number of layers of the passivation reinforcing layers formed on the edge of the passivation layer 13 may be one or more. In order to further improve the packaging effect of OLED devices, in embodiments of the present invention, a plurality of passivation layers 13 are formed on the surfaces of OLED devices and at least one passivation reinforcing layer is formed on the edge of the passivation layer 13. For example, it is possible to form a plurality of passivation layers 13 on the surfaces of OLED devices and form a passivation reinforcing layer accordingly on the edge layer of each passivation layer 13. It is possible to form a plurality of passivation layers 13 on the surfaces of OLED devices and form a passivation reinforcing layer on the edge of partial passivation layers 13 respectively. It is possible to form a plurality of passivation layers 13 on the surfaces of OLED devices and form a plurality of passivation reinforcing layers on the edge of one of the passivation layers 13. And it is possible to form a plurality of passivation layers 13 on the surfaces of OLED devices and form a passivation reinforcing layer on the edge of one of the passivation layers 13.

Materials for forming the plurality of passivation layers 13 may the same or different. Considering that a passivation layer of inorganic material has high water-tightness and oxygen-tightness while a passivation layer of organic material has better film forming ability, for example, the passivation layer 13 may be a multi-layered stackup structure formed by stacking inorganic material and organic material alternatively. In this way, it is not only possible to enhance water-tightness and oxygen-tightness of the passivation layer 13, but also possible to effectively improve the performance of the passivation layer 13, thereby further improving the packaging effect of OLED devices and prolonging the service life of OLED devices.

It is to be noted that materials for forming the passivation layer 13 and the passivation reinforcing layer may be the same or different. For example, the passivation layer 13 may be one of inorganic material such as silicon nitride (SiNₓ), silicon oxide (SiOₓ) or silicon oxynitride (SiOₓN_{y}), or may be one of organic material such as polymers; and the passivation reinforcing layer may be one of inorganic material or one of organic material. In order to improve the packaging effect of OLED devices, for example, the passivation layer 13 and the passivation reinforcing layer are formed of the same material to improve the interface boding performance between the passivation reinforcing layer and the passivation layer 13, thereby improving the packaging effect of OLED devices and further prolonging the service life of OLED devices.

As shown in FIG. 1, The packaging method of an OLED device provided in an embodiment of the present invention further includes:

S104, forming an adhesive film on the passivation layer 13 and the passivation reinforcing layer;

S105, cell-assembling the packaging cover plate and the base substrate via the adhesive film to form a cell, and the OLED device, the passivation layer 13 and the passivation reinforcing layer are located in the cell formed by the packaging cover plate and the base substrate.

Forming the adhesive film on the passivation layer 13 and the passivation reinforcing layer and cell-assembling the packaging cover plate and the base substrate via the adhesive film to form a cell, as a result, the OLED device, the passivation layer 13 and the passivation reinforcing layer are located in the cell formed by the packaging cover plate and the base substrate. Through the above settings, the passivation layer 13 and the passivation reinforcing layer are prevented from being aged due to long time exposure, thereby guaranteeing the packaging effect of OLED devices and prolonging the service life of OLED devices.

An embodiment of the present invention further provides a packaging structure for an OLED device as shown in FIG. 7, which includes: a base substrate 11, an OLED devices 12 on the base substrate 11, a passivation layer 13 overlaying the OLED device 12, and a passivation reinforcing layer 14 disposed on the edge of the passivation layer 13.

The measured thickness of the edge of the passivation layer 13 is less than or equal to one half of the preset thickness of the passivation layer 13; and the preset thickness of the passivation reinforcing layer 14 is greater than the measured thickness of the edge of the passivation layer 13.

In this embodiment, there is a plurality of the passivation layers 13 and there is at least one passivation reinforcing layer 14. The passivation layer 13 is a multi-layered stackup structure formed by alternatively stacking inorganic material and organic material.

In an embodiment of the present invention, the packaging structure of OLED device further includes: an adhesive film 15 on the passivation layer 13 and the passivation reinforcing layer 14 and a packaging cover plate 16 cell-assembling with the base substrate 11 through adhesive films 15 to form a cell.

Embodiments in the present specification are described in a progressive manner such that same or similar parts among embodiments may be cross referenced and each embodiment is described focusing on the differences from other embodiments. Especially, for product embodiments, since they are substantially similar to method embodiments, they may be described simpler and parts of method embodiments may be referred to for relevant parts.

An embodiment of the present invention further provides a display device that is provided with the packaging structure of OLED device as described above.

The display device has the same advantages over conventional solutions as the packaging structure of OLED device provided in the above-mentioned embodiments, which will not be described any more herein.

Specifically, the display device may be any product or component with display function such as electronic paper, a mobile telephone, a tablet computer, a TV set, a notebook computer, a digital picture frame or a navigator.

In the description of the above-mentioned implementations, specific features, structures, materials or characteristics may be combined in proper manner in any one or more embodiments or examples.

The above are only the model implementation ways of the present disclosure, and not used to limit the scope of protection of the present disclosure, the scope of protection of the present disclosure is determined by the attached claims.

The present application claims the priority of the Chinese Patent Application No. 201510229716.3 filed on May 7, 2015, which is incorporated herein by reference as part of the disclosure of the present application.

1. A packaging method for an organic light emitting diode (OLED) device, comprising:
providing a base substrate formed with the OLED device;
forming at least one passivation layer on a surface of the OLED device; and
forming at least one passivation reinforcing layer on an edge of the at least one passivation layer.

2. The packaging method of the OLED device of claim 1, wherein forming at least one passivation reinforcing layer on the edge of the at least one passivation layer comprises:
forming a first reinforcing section on a partial region of the edge of the at least one passivation layer with a first mask; and
forming a second reinforcing section on the edge of the at least one passivation layer with a second mask, wherein the first reinforcing section together with the second reinforcing section cover the edge of the passivation layer.

3. The packaging method of the OLED device of claim 1, wherein forming at least one passivation reinforcing layer on the edge of the at least one passivation layer comprises:
forming the passivation reinforcing layer on the edge of the at least one passivation layer with a third mask.

4. The packaging method of the OLED device of claim 1, wherein a measured thickness of the edge of the at least one passivation layer is less than or equal to one half of a preset thickness of the at least one passivation layer.

5. The packaging method of the OLED device of claim 4, wherein a preset thickness of the at least one passivation reinforcing layer is greater than the measured thickness of the at least one passivation layer.

6. The packaging method of the OLED device of claim 1, wherein a plurality of the passivation layers are formed on the surface of the OLED device.

7. The packaging method of the OLED device of claim 6, wherein the plurality of the passivation layers are a multi-layer stackup structure formed by alternatively stacking an inorganic material and an organic material.

8. The packaging method of the OLED device of claim 1 further comprising:
forming an adhesive film on the at least one passivation layer and the at least one passivation reinforcing layer;
cell-assembling a packaging cover plate with the base substrate by the adhesive film to form a cell, wherein the OLED device, the at least one passivation layer and the at least one passivation reinforcing layer are located in the cell formed by the cover plate and the base substrate.

9. A packaging structure of an organic light emitting diode (OLED) device, comprising:
at least one passivation layer overlaying on a surface of an OLED device on a base substrate, and
at least one passivation reinforcing layer disposed on an edge of the at least one passivation layer.

10. The packaging structure of the OLED device of claim 9, wherein a measured thickness of the edge of the at least one passivation layer is less than or equal to one half of a preset thickness of the at least one passivation layer.

11. The packaging structure of the OLED device of claim 10, wherein a preset thickness of the at least one passivation reinforcing layer is greater than the measured thickness of the at least one passivation layer.

12. The packaging structure of the OLED device of claim 9, wherein a plurality of the passivation layers are provided.

13. The packaging structure of the OLED device of claim 12, wherein the plurality of the passivation layers are a multi-layer stack-up structure formed by alternatively stacking inorganic material and organic material.

14. The packaging structure of the OLED device of claim 9, further comprising:
an adhesive film on the at least one passivation layer and the at least one passivation reinforcing layer, and
a packaging cover plate cell-assembling with the base substrate through the adhesive film to form a cell.

15. A display device provided with the packaging structure of OLED devices of claim 9.

16. The packaging method of the OLED device of claim 2, wherein a measured thickness of the edge of the at least one passivation layer is less than or equal to one half of a preset thickness of the at least one passivation layer.

17. The packaging method of the OLED device of claim 3, wherein a measured thickness of the edge of the at least one passivation layer is less than or equal to one half of a preset thickness of the at least one passivation layer.

18. The packaging method of the OLED device of claim 2, wherein a plurality of the passivation layers are formed on the surface of the OLED device.

19. The packaging method of the OLED device of claim 3, wherein a plurality of the passivation layers are formed on the surface of the OLED device.

20. The packaging method of the OLED device of claim 2, further comprising:
forming an adhesive film on the at least one passivation layer and the at least one passivation reinforcing layer;
cell-assembling a packaging cover plate with the base substrate by the adhesive film to form a cell, wherein the OLED device, the at least one passivation layer and the at least one passivation reinforcing layer are located in the cell formed by the cover plate and the base substrate.
